(19) United States
(12) Patent Application Publication
(10) Pub. No.: US 2024/0162181 A1
(43) Pub. Date: May 16, 2024

(54) SEMICONDUCTOR PACKAGES

(71) Applicant: SAMSUNG ELECTRONICS CO., LTD., Suwon-si (KR)

(72) Inventors: Sun Jae KIM, Suwon-si (KR); Sun Kyoung SEO, Suwon-si (KR); Cha Jea JO, Suwon-si (KR)

(21) Appl. No.: 18/486,831

(22) Filed: Oct. 13, 2023

(30) Foreign Application Priority Data
Nov. 16, 2022 (KR) 10-2022-0153436

(51) Int. Cl. H01L 23/00; H01L 23/498; H01L 23/544; H01L 25/065; H01L 25/18; H10B 80/00

(52) U.S. Cl. CPC H01L 24/17; H01L 23/49838; H01L 23/544; H01L 24/05; H01L 24/06; H01L 24/13; H01L 24/14; H01L 24/16; H01L 24/29; H01L 24/32; H01L 24/73; H01L 25/0657; H01L 25/18; H10B 80/00; H01L 24/03; H01L 24/11; H01L 24/33; H01L 2223/54426; H01L 2224/0346; H01L 2224/03466; H01L 2224/05011; H01L 2224/05015; H01L 2224/05018; H01L 2224/05024; H01L 2224/05073; H01L 2224/05166; H01L 2224/05541; H01L 2224/05551; H01L 2224/05552; H01L 2224/05553; H01L 2224/05555; H01L 2224/0557; H01L 2224/05573; H01L 2224/05655; H01L 2224/0603; H01L 2224/06051; H01L 2224/06181; H01L 2224/1146; H01L 2224/11849; H01L 2224/13109; H01L 2224/13111; H01L 2224/13113; H01L 2224/13116; H01L 2224/13118; H01L 2224/1312; H01L 2224/13139; H01L 2224/13147; H01L 2224/1403; H01L 2224/16145; H01L 2224/16227; H01L 2224/1703; H01L 2224/17181; H01L 2224/17517; H01L 2224/2929; H01L 2224/29386; H01L 2224/32145; H01L 2224/32225; H01L 2224/33181; H01L 2224/73204; H01L 2224/73253; H01L 2225/06513; H01L 2225/06517; H01L 2225/06541; H01L 2924/04642; H01L 2924/0503; H01L 2924/0532; H01L 2924/0543; H01L 2924/05432; H01L 2924/05442; H01L 2924/0549; H01L 2924/059; H01L 2924/0665; H01L 2924/1431; H01L 2924/14361; H01L 2924/1437; H01L 2924/1441; H01L 2924/1443

(57) ABSTRACT

A semiconductor package comprising: a first semiconductor chip extending in each of first and second directions that intersect each other; a second semiconductor chip on the first semiconductor chip in a third direction perpendicular to the first and second directions, wherein the second semiconductor chip includes a first area and a second area that is adjacent to and extends around the first area; and a bump structure and a conductive material layer between the first and second semiconductor chips, wherein the conductive material layer is on the bump structure, wherein the bump structure includes a first bump structure overlapping the first area in the third direction, and a second bump structure overlapping the second area in the third direction, wherein the first and second bump structures are spaced apart from each other, and a thickness of the second bump structure is larger than a thickness of the first bump structure.

### CROSS-REFERENCE TO RELATED APPLICATION

This application claims priority to Korean Patent Application No. 10-2022-0153436 filed on Nov. 16, 2022 in the Korean Intellectual Property Office, and all the benefits accruing therefrom under 35 U.S.C. 119, the contents of which in its entirety are herein incorporated by reference.

### BACKGROUND

The present disclosure relates to semiconductor packages.

A semiconductor package may include a plurality of semiconductor chips stacked on a substrate. These semiconductor chips may be electrically connected to each other via a connection structure including a conductive bump and a pad.

In this case, in a process of bonding an upper structure (e.g., an upper semiconductor chip of the plurality of semiconductor chips) and a lower structure (e.g., a lower semiconductor chip of the plurality of semiconductor chips) to each other, misalignment of the plurality of semiconductor chips may occur due to sweep of the bump.

### SUMMARY

Technical features of the present disclosure may provide a semiconductor package in which a structure of a bump is adapted so as to reduce misalignment of semiconductor chips in the semiconductor package.

The technical features of the present disclosure are not limited to the above-mentioned features. Other features of the present disclosure that are not mentioned may be understood based on following descriptions and may be more clearly understood based on embodiments according to the present disclosure. Further, it will be easily understood that the purposes and advantages according to the technical features of the present disclosure may be realized using means shown in the claims or combinations thereof.

According to some embodiments, a semiconductor package comprising: a first semiconductor chip, wherein the first semiconductor chip extends in each of first and second directions that intersect each other; a second semiconductor chip stacked on the first semiconductor chip in a third direction perpendicular to each of the first and second directions, wherein the second semiconductor chip includes a first area and a second area that is adjacent to and extends around the first area; a bump structure between the first and second semiconductor chips; and a conductive material layer between the first and second semiconductor chips, wherein the conductive material layer is on the bump structure, wherein the bump structure includes a first bump structure overlapping the first area in the third direction, and a second bump structure overlapping the second area in the third direction, wherein the first bump structure and the second bump structure are spaced apart from each other, and wherein a thickness of the second bump structure in the third direction is larger than a thickness of the first bump structure in the third direction.

According to some embodiments, a semiconductor package comprising: a first semiconductor chip, wherein the first semiconductor chip extends in each of first and second directions that intersect each other; a second semiconductor chip stacked on the first semiconductor chip in a third direction perpendicular to each of the first and second directions, wherein the second semiconductor chip includes a first area and a second area that is adjacent to and extends around the first area; a bump structure between the first and second semiconductor chips; and a conductive material layer between the first and second semiconductor chips, wherein the conductive material surrounds a portion of the bump structure, wherein the bump structure includes: a connection bump structure overlapping the first area in the third direction and electrically connected to the first and second semiconductor chips; and a dummy bump structure overlapping the second area in the third direction and electrically insulated from the first and second semiconductor chips, wherein the connection bump structure and the dummy bump structure are spaced apart from each other, and wherein a thickness of the dummy bump structure in the third direction is larger than a thickness of the connection bump structure in the third direction.

According to some embodiments, a semiconductor package comprising: a substrate, wherein the substrate extends in each of first and second directions that intersect each other; a first semiconductor chip stacked on the substrate in a third direction perpendicular to each of the first and second directions; a second semiconductor chip stacked on the first semiconductor chip in the third direction, wherein the second semiconductor chip includes a first area and a second area that is adjacent to and extends around the first area; a bump structure that is configured to bond the first semiconductor chip and the second semiconductor chip to each other between the first semiconductor chip and the second semiconductor chip; and a conductive material layer between the first and second semiconductor chips, wherein the conductive material surrounds a portion of the bump structure, wherein the first semiconductor chip includes a through-via extending through at least a portion of the first semiconductor chip, wherein the through-via electrically connects the second semiconductor chip and the substrate to each other, wherein the bump structure includes a first bump structure overlapping the first area in the third direction, and a second bump structure overlapping the second area in the third direction, and wherein a thickness of the first bump structure in the third direction is different from a thickness of the second bump structure in the third direction.

Details of other embodiments are included in the detailed descriptions and the drawings.

### BRIEF DESCRIPTION OF DRAWINGS

The above and other aspects and features of the present disclosure will become more apparent by describing in detail illustrative embodiments thereof with reference to the attached drawings, in which:

FIG. 1 is a plan view of an illustrative layout diagram of a semiconductor package according to some embodiments of the present disclosure;

FIG. 2 is a cross-sectional view taken along a line I-I′ of FIG. 1;

FIG. 3 is an enlarged view to illustrate an area R1 in FIG. 2;

FIG. 4A to FIG. 4E are plan views of a pad in various shapes on which a bump structure of FIG. 2 is disposed;

FIG. 5 is a plan view of an illustrative layout diagram of a semiconductor package according to some embodiments of the present disclosure;

FIG. 6 to FIG. 9 are diagrams in cross-sectional views for illustrating a method for manufacturing a semiconductor package according to some embodiments of the present disclosure;

FIG. 10 to FIG. 13 are diagrams in cross-sectional views for illustrating a method for manufacturing a semiconductor package according to some embodiments of the present disclosure;

FIG. 14 is a diagram in a cross-sectional view for illustrating a semiconductor package according to some embodiments of the present disclosure;

FIG. 15 is a diagram in a cross-sectional view for illustrating a semiconductor package according to some embodiments of the present disclosure; and

FIG. 16 is a diagram in a cross-sectional view for illustrating a semiconductor package according to some embodiments of the present disclosure.

### DETAILED DESCRIPTIONS

For simplicity and clarity of illustration, elements in the drawings may not be necessarily drawn to scale. The same reference numbers in different drawings may represent the same or similar elements, and as such may perform similar functionality. Further, descriptions and details of well-known steps and elements may be omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits may not be described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the scope of the present disclosure as defined by the appended claims.

A shape, a size, a ratio, an angle, a number, etc. disclosed in the drawings for illustrating embodiments of the present disclosure are illustrative, and the present disclosure is not limited thereto. The same reference numerals may refer to the same elements herein. Further, descriptions and details of well-known steps and elements may be omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits may not be described in detail so as not to unnecessarily obscure aspects of the present disclosure.

The terminology used herein is for the purpose of describing particular embodiments only and is not intended to limit the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify an entirety of list of elements and may not modify the individual elements of the list. When referring to “C to D”, this means C inclusive to D inclusive unless otherwise specified.

It will be understood that, although the terms “first”, “second”, “third”, and so on may be used herein to illustrate various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the scope of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is disposed “directly on” or “directly on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is disposed “directly below” or “directly under” another layer, film, region, plate, or the like, the former directly contacts the latter and still another layer, film, region, plate, or the like is not disposed between the former and the latter.

In one example, when a certain embodiment may be implemented differently, a function or operation specified in a specific block may occur in a sequence different from that specified in a flowchart. For example, two consecutive blocks may actually be executed at the same time. Depending on a related function or operation, the blocks may be executed in a reverse sequence. Moreover, the function or operation in the specific block (e.g., step) may be separated into multiple blocks (e.g., steps) and/or may be at least partially integrated.

In descriptions of temporal relationships, for example, temporal precedent relationships between two events such as “after”, “subsequent to”, “before”, etc., another event may occur therebetween unless “directly after”, “directly subsequent” or “directly before” is not indicated.

The features of the various embodiments of the present disclosure may be partially or entirely combined with each other, and may be technically associated with each other or operate with each other. The embodiments may be implemented independently of each other and may be implemented together in an association relationship.

Spatially relative terms, such as “beneath,” “below,” “lower,” “under,” “above,” “upper,” and the like, may be used herein for ease of explanation to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

Hereinafter, embodiments according to the technical idea of the present disclosure will be described with reference to the accompanying drawings.

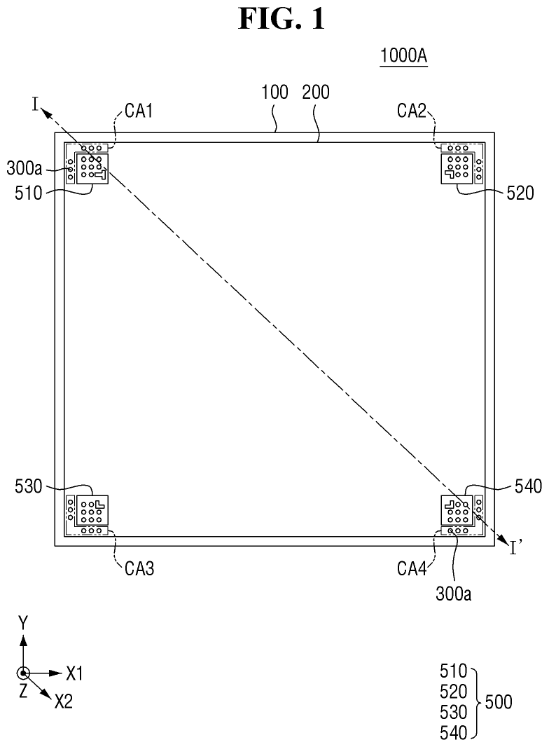

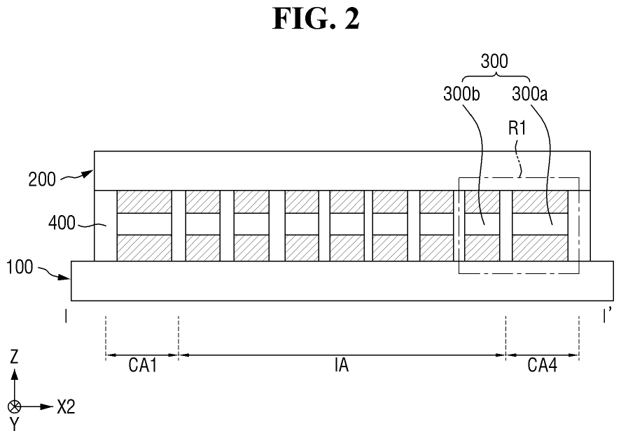

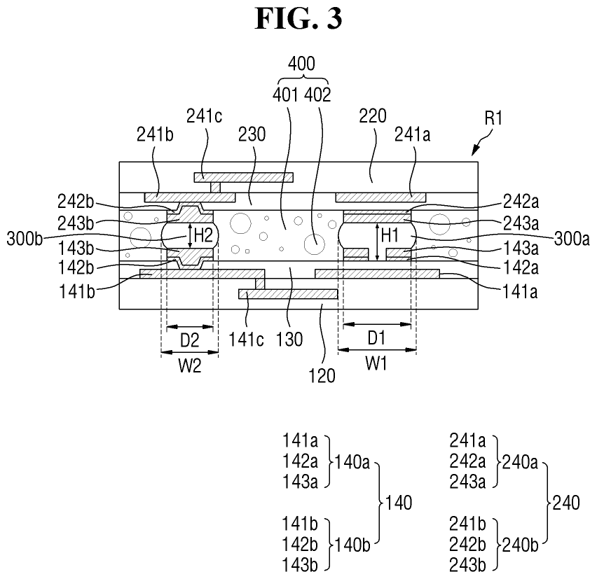

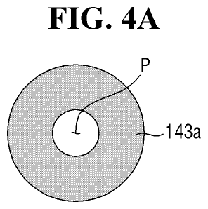

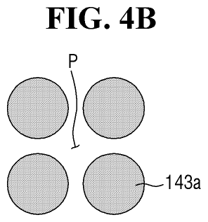

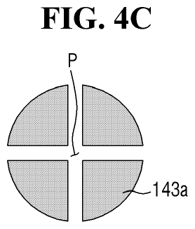

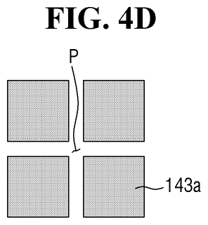

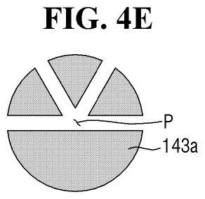

FIG. 1 is a plan view of an illustrative layout diagram of a semiconductor package according to some embodiments of the present disclosure. FIG. 2 is a cross-sectional view taken along a line I-I′ of FIG. 1. FIG. 3 is an enlarged view to illustrate an area R1 in FIG. 2. FIG. 4A to FIG. 4E are plan views of a pad in various shapes on which a bump structure of FIG. 2 is disposed. For reference, FIG. 4A to FIG. 4E may be top views of the pad.

In some embodiments, each of a first direction X1, a second direction X2, and a third direction Y may be a direction parallel to a top face of a first semiconductor chip 100. The first direction X1, the second direction X2, and the third direction Y may intersect each other. For example, the first direction X1 and the third direction Y may intersect each other perpendicularly. For example, the first direction X1 and the second direction X2 may intersect each other in an oblique direction. The second direction X2 and the third direction Y may intersect each other in an oblique direction.

A fourth direction Z may be a direction perpendicular to the top face of the first semiconductor chip 100. The fourth direction Z may be a direction perpendicular to each of the first direction X1, the second direction X2, and the third direction Y.

A semiconductor package 1000A according to some embodiments of the present disclosure may include the first semiconductor chip 100, a second semiconductor chip 200, and a bump structure 300, and may further include a conductive material layer 400 and an alignment pattern 500.

The first semiconductor chip 100 may be disposed under the second semiconductor chip 200 to be described later. For example, the second semiconductor chip may be on the first semiconductor chip 100 and/or overlap the first semiconductor chip 100 in the fourth direction Z. The first semiconductor chip 100 may extend in each of the first to third directions X1, X2, and Y intersecting each other.

The first semiconductor chip 100 may include a first semiconductor device layer 120 and a first passivation layer 130 on the first semiconductor device layer 120. The first semiconductor device layer 120 may be an area where transistors are disposed, and the first passivation layer 130 may be an area where a plurality of wirings to electrically connect the first semiconductor chip 100 to the second semiconductor chip 200 are disposed.

Although not specifically shown, the first semiconductor device layer 120 may include a semiconductor substrate and devices disposed on the semiconductor substrate.

The semiconductor substrate may be for example, bulk silicon or SOI (silicon-on-insulator). In some embodiments, the semiconductor substrate may be, for example, a silicon substrate. The semiconductor substrate may include, but is not limited to, silicon germanium, SGOI (silicon germanium on insulator), indium antimonide, a lead telluride compound, indium arsenide, indium phosphide, gallium arsenide, or gallium antimonide.

The semiconductor substrate may include a conductive area, for example, a well doped with impurities or a structure doped with impurities. The semiconductor substrate may have various device isolation structures such as an STI (shallow trench isolation) structure.

The first semiconductor device layer 120 may include a plurality of individual devices of various types, and an interlayer insulating film. The individual devices may include various microelectronic devices, for example, a MOSFET (metal-oxide-semiconductor field effect transistor) such as a CMOS transistor (complementary metal-insulator-semiconductor transistor), a system LSI (large scale integration), a flash memory, a DRAM (dynamic random access memory), a SRAM (static random access memory), an EEPROM (electrically erasable programmable read-only memory), a PRAM (phase-change random access memory), a MRAM (magnetoresistive random access memory), a FeRAM (ferroelectric random access memory), a RRAM (resistive random access memory), an image sensor such as a CIS (CMOS imaging sensor), a MEMS (micro-electro-mechanical system), an active device, a passive device, etc.

The individual devices of the first semiconductor device layer 120 may be electrically connected to the conductive area formed in the semiconductor substrate. Each of the individual devices of the first semiconductor device layer 120 may be electrically isolated from each of other individual devices adjacent thereto via each of various device isolation structures such as insulating films. The first semiconductor device layer 120 may include wiring structures electrically connecting at least two of the plurality of individual devices or the plurality of individual devices to the conductive area of the semiconductor substrate. Further, the first semiconductor device layer 120 may include first wiring structures 141c electrically connected to a portion of the bump structure 300 (e.g., first-second solder bump 300b) to be described later.

The first passivation layer 130 may include at least a portion of a first wiring layer 140 between the first semiconductor device layer 120 and the second semiconductor chip 200. The first wiring layer 140 may include a first-first wiring layer 140a that does not electrically connect the first semiconductor device layer 120 and the second semiconductor chip 200 to each other and a first-second wiring layer 140b that electrically connects the first semiconductor device layer 120 and the second semiconductor chip 200 to each other.

The first passivation layer 130 may include, for example, a photosensitive insulating material (PID; a photoimageable dielectric). However, the present disclosure is not limited thereto.

The first-first wiring layer 140a may include first-first-first to third-first-first wiring pads 141a, 142a, and 143a stacked in the fourth direction Z.

The first-first-first wiring pad 141a may be disposed on the first semiconductor device layer 120. The second-first-first wiring pad 142a may be spaced apart from the first-first-first wiring pad 141a in the fourth direction Z while being disposed on the first passivation layer 130. The third-first-first wiring pad 143a may be disposed on the second-first-first wiring pad 142a.

The first-second wiring layer 140b may include first-first-second to third-first-second wiring pads 141b, 142b, and 143b stacked in the fourth direction Z.

The first-first-second wiring pad 141b may be disposed on the first semiconductor device layer 120. The second-first-second wiring pad 142b may be disposed on the first passivation layer 130 so as to contact the first-first-second wiring pad 141b. The third-first-second wiring pad 143b may be disposed on the second-first-second wiring pad 142b.

The second semiconductor chip 200 may be disposed on the first semiconductor chip 100. The second semiconductor chip 200 extends in each of the first to third directions X1, X2, and Y intersecting each other. Referring to FIGS. 1 and 2, the second semiconductor chip 200 may include an inner area IA and an outer area CA adjacent to and extending around (e.g., surrounding) the inner area IA. Referring to FIG. 1, the outer area CA may include first to fourth outer areas CA1, CA2, CA3, and CA4, respectively disposed adjacent to four corners of the second semiconductor chip 200.

The second semiconductor chip 200 may include a second semiconductor device layer 220 and a second passivation layer 230 on the second semiconductor device layer 220. The second passivation layer 230 may face the first passivation laye4r 130. The second semiconductor device layer 220 may be an area where transistors are disposed, and the second passivation layer 230 may be an area where a plurality of wirings to electrically connect the second semiconductor chip 200 to the first semiconductor chip 100 are disposed. In some embodiments, the second semiconductor device layer 220 may be on the first passivation layer 130, and the second passivation layer 230 may be between the second semiconductor device layer 220 and the first passivation layer 130 in the fourth direction Z. The first passivation layer 130 may be between the second passivation layer 230 and the first semiconductor device layer 120 in the fourth direction Z.

Although not specifically shown, the second semiconductor device layer 220 may include a semiconductor substrate, and devices disposed on the semiconductor substrate. The descriptions about the semiconductor substrate and the devices of the first semiconductor device layer 120 as set forth above may be equally applied to those regarding the semiconductor substrate and the devices of the second semiconductor device layer 220.

A plurality of individual devices of the second semiconductor device layer 220 may be electrically connected to a conductive area formed in the semiconductor substrate thereof. Each of the individual devices of the second semiconductor device layer 220 may be electrically isolated from each of other individual devices adjacent thereto via each of various device isolation structures such as insulating films. The second semiconductor device layer 220 may include wiring structures electrically connecting at least two of the plurality of individual devices or the plurality of individual devices to the conductive area of the semiconductor substrate.

Further, the second semiconductor device layer 220 may include second wiring structures 241c electrically connected to a portion of the bump structure 300 (e.g., first-second solder bump 300b) to be described later.

Each of the first semiconductor chip 100 and the second semiconductor chip 200 may be a logic chip, a memory chip, or a combination thereof. The first semiconductor chip 100 and the second semiconductor chip 200 may be of the same type. For example, each of the first semiconductor chip 100 and the second semiconductor chip 200 may be a volatile memory chip such as DRAM or SRAM. In some embodiments, each of the first semiconductor chip 100 and the second semiconductor chip 200 may be a nonvolatile memory chip such as PRAM, MRAM, FeRAM, or RRAM.

In some embodiments, one of the first semiconductor chip 100 and the second semiconductor chip 200 may be a memory chip and the other thereof may be a logic chip. For example, the second semiconductor chip 200 may be a volatile memory chip such as DRAM or SRAM, while the first semiconductor chip 100 may be a logic chip.

In some embodiments, the second semiconductor chip 200 may be a volatile memory chip such as DRAM or SRAM, while the first semiconductor chip 100 may be a MOSFET such as a CMOS transistor, etc.

In some embodiments, one of the first semiconductor chip 100 and the second semiconductor chip 200 may be a microprocessor, an analog device, a digital signal processor, or an application processor. In some embodiments, one of the first semiconductor chip 100 and the second semiconductor chip 200 may be a HBM (high bandwidth memory).

The second passivation layer 230 may include a second wiring layer 240 between the second semiconductor device layer 220 and the first semiconductor chip 100. The second wiring layer 240 may include a second-first wiring layer 240a that does not electrically connect the second semiconductor device layer 220 and the first semiconductor chip 100 to each other and a second-second wiring layer 240b that electrically connects the second semiconductor device layer 220 and the first semiconductor chip 100 to each other.

The second passivation layer 230 may include, for example, a photosensitive insulating material (e.g., PID). However, the present disclosure is not limited thereto.

The second-first wiring layer 240a may include first-second-first to third-second-first wiring pads 241a, 242a, and 243a stacked in the fourth direction Z.

The first-second-first wiring pad 241a may be disposed on the second semiconductor device layer 220. The second-second-first wiring pad 242a may be spaced apart from the first-second-first wiring pad 241a in the fourth direction Z while being disposed on the second passivation layer 230. The third-second-first wiring pad 243a may be disposed on the second-second-first wiring pad 242a.

The second-second wiring layer 240b may include first-second-second to third-second-second wiring pads 241b, 242b, and 243b stacked in the fourth direction Z.

The first-second-second wiring pad 241b may be disposed on the second semiconductor device layer 220. The second-second-second wiring pad 242b may be disposed on the second passivation layer 230 so as to contact the first-second-second wiring pad 241b. The third-second-second wiring pad 243b may be disposed on the second-second-second wiring pad 242b.

Each of the first and second wiring layers 140 and 240 may have a stack structure of multiple layers. Although not specifically shown, each of the first and second wiring layers 140 and 240 may further include, therein, a plurality of vias for electrically connecting the first and second semiconductor chips 100 and 200 to each other.

Each of the first and second wiring layers 140 and 240 may include, for example, a conductive material. For example, each of the first and second wiring layers 140 and 240 may include copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc, (Zn), carbon (C) and/or a metal alloy thereof.

The bump structure 300 may be disposed between the first and second semiconductor chips 100 and 200 so as to connect the first and second semiconductor chips 100 and 200 to each other. For example, the bump structure 300 may be used to bond the first and second semiconductor chips 100 and 200 to each other in a bonding process for bonding the first and second semiconductor chips 100 and 200 to each other.

The bump structure 300 may include a first-second bump structure having a first-second solder bump 300b disposed in the inner area IA and first-first bump structure having a first-first solder bump 300a disposed in the outer area CA. In some embodiments, the first-second solder bump 300b may be overlapped with the inner area IA in the fourth direction Z and the first-first solder bump 300a may be overlapped with the outer area CA in the fourth direction Z. The first-second solder bump 300b and the first-first solder bump 300a may be spaced apart from each other. The first-second solder bump 300b and the first-first solder bump 300a may have a solder bump structure, but the present disclosure is not limited thereto. The first-second solder bump 300b may be referred to as a connection bump structure and the first-first solder bump 300a may be referred to as a dummy bump structure.

The first-second solder bump 300b may be disposed between the third-first-second wiring pad 143b of the first semiconductor chip 100 and the third-second-second wiring pad 243b of the second semiconductor chip 200. The first-first solder bump 300a may be disposed between the third-first-first wiring pad 143a of the first semiconductor chip 100 and the third-second-first wiring pad 243a of the second semiconductor chip 200.

Referring to FIG. 3, a width W2 (e.g., maximum width) of the first-second solder bump 300b in the second direction X2 may be equal to or greater than a width D2 of each of the second-first-second wiring pad 142b and the third-first-second wiring pad 143b in the second direction X2.

For example, the width W2 of the first-second solder bump 300b in the second direction X2 may be in a range of 13 to 20 micrometers (μm). The width D2 of each of the second-first-second wiring pad 142b and the third-first-second wiring pad 143b in the second direction X2 may be in a range of 13 to 20 μm. However, the present disclosure is not limited thereto.

Referring to FIG. 3, a width W1 (e.g., maximum width) of the first-first solder bump 300a may be equal to or greater than a width D1 of each of the second-first-first wiring pad 142a and the third-first-first wiring pad 143a in the second direction X2.

For example, the width W1 the first-first solder bump 300a in the second direction X2 may be in a range of 20 to 60 μm. The width D1 of each of the second-first-first wiring pad 142a and the third-first-first wiring pad 143a in the second direction X2 may be in a range of 20 to 60 μm. However, the present disclosure is not limited thereto.

Each of the first-first solder bump 300a and the first-second solder bump 300b may have, for example, a spherical or elliptical cross-sectional shape. However, the present disclosure is not limited thereto. Each of the first-first solder bump 300a and the first-second solder bump 300b may include, for example, tin (Sn), indium (In), bismuth (Bi), antimony (Sb), copper (Cu), silver (Ag), zinc (Zn), lead (Pb), and/or combinations thereof. However, the present disclosure is not limited thereto.

Referring to FIG. 3 and FIG. 4A, each of the second-first-first wiring pad 142a and the third-first-first wiring pad 143a may include a plurality of pads (e.g., sub-pads) spaced apart from each other in the second direction X2. The first-first solder bumps 300a may be respectively disposed between adjacent ones of the plurality of second-first-first wiring pads 142a spaced apart from each other in the second direction X2, and between adjacent ones of the plurality of third-first-first wiring pads 143a spaced apart from each other in the second direction X2.

In this case, a thickness of the first-first bump structure in the fourth direction Z may be larger than a thickness of the first-second bump structure in the fourth direction Z. For example, a thickness of the first-first solder bump 300a in the fourth direction Z may be different from a thickness of the first-second solder bump 300b in the fourth direction Z. Specifically, a length H1 (e.g., thickness) of the first-first solder bump 300a in the fourth direction Z may be larger than a length H2 (e.g., thickness) of the first-second solder bump 300b along the fourth direction Z.

A length of the first-first solder bump 300a in the second direction X2 may be different from a length of the first-second solder bump 300b in the second direction X2. Specifically, the width W1 (e.g., maximum width) of the first-first solder bump 300a in the second direction X2 may be larger than the width W2 (e.g., maximum width) of the first-second solder bump 300b in the second direction X2. In some embodiments, the first wiring structures 141c of the first semiconductor chip 100 and the second wiring structures 241c of the second semiconductor chip 200 may be electrically connected to the first-second solder bump 300b but may be electrically disconnected from the first-first solder bump 300a. According to some embodiments, the first-second solder bump 300b may be electrically connected to the first semiconductor chip 100 and the second semiconductor chip 200, and the first-first solder bump 300a may be electrically insulated from the first semiconductor chip 100 and the second semiconductor chip 200.

Referring to FIG. 3 and FIG. 4A, the third-first-first wiring pad 143a may have an elliptical shape or a circular shape in a plan view and the third-first-first wiring pad 143 may have a separation space P therein. In some embodiments, the separation space P may have an elliptical shape or a circular shape in a plan view but is not limited thereto. For example, a width (e.g., D1) of the third-first-first wiring pad 143a in the second direction X2 may be in a range of 20 to 60 μm, and a width (e.g., W1) of the first-first solder bump 300a in the second direction X2 may be in a range of 20 to 60 μm. However, the present disclosure is not limited thereto.

According to some embodiments, the separation space (e.g., separation space P) may be defined in the pad (e.g., third-first-first wiring pad 143) disposed on an outer portion (e.g., first to fourth outer areas CA1, CA2, CA3, and CA4) of the semiconductor chip (e.g., second semiconductor chip 200) so that the solder bump (e.g., first-first solder bump 300a) is buried in the separation space. Accordingly, a thickness of a portion of the solder bump (e.g., in the fourth direction Z) disposed on the outer portion of the semiconductor chip may be greater than that of a portion of the solder bump (e.g., first-second solder bump 300b) adjacent to a center portion of the semiconductor chip. Further, a width (e.g., W1) of the portion of the solder bump (e.g., in the second direction X2) disposed on the outer portion may be greater than that of (e.g., W2) the portion of the solder bump adjacent to the center portion of the semiconductor chip.

Accordingly, during a reflow process, as described later, defects such as non-wet defects caused by sweep or tilt of the solder bump may be reduced (e.g., prevented) using surface tension of the liquid solder bump (e.g., liquid status of the first-first solder bump 300a), thereby improving the assembly yield of the semiconductor package.

Further, according to some embodiments, the portion of the solder bump (e.g., first-first solder bump 300a) disposed on the outer portion of the semiconductor chip may itself function as an alignment pattern. That is, since a shape of the portion of the solder bump disposed on the outer portion of the semiconductor chip may be recognized using a vision recognizer, misalignment of the semiconductor package may be minimized more effectively.

Referring to FIG. 4B, the third-first-first wiring pad 143a may include a plurality of elliptical pads and/or circular pads spaced apart from each other in a plan view. In this case, an area of the separation space P of the third-first-first wiring pad 143a of FIG. 4B may be larger than that of the separation space P of the third-first-first wiring pad 143a of FIG. 4A, such that an amount of the solder bump (e.g., first-first solder bump 300a) buried in the separation space P between the plurality of elliptical pads and/or circular pads (of third-first-first wiring pads 143a) spaced from each other may further increase.

Referring to FIG. 4C, the third-first-first wiring pad 143a may include pads having an elliptical sector shape and/or a circular sector shape and spaced apart from each other. Referring to FIG. 4D, the third-first-first wiring pad 143a may include rectangular pads spaced apart from each other. Referring to FIG. 4E, the third-first-first wiring pad 143a may include pads having curved portions, such as elliptical sector shaped-pads and/or circular sector-shaped pads and a semi-elliptical pad or a semi-circular pad spaced apart from each other.

In each of FIG. 4C to FIG. 4E, the area of the separation space P may be smaller than that of the separation space P of the third-first-first wiring pad 143a in FIG. 4B, so that the amount of the solder bump buried in the separation space P between the plurality of third-first-first wiring pads 143a spaced from each other in FIG. 4C to FIG. 4E may be reduced compared to that of FIG. 4B.

That is, in some embodiments, the amount of the solder bump buried in the separation space may be adjusted by variously changing the shape of the wiring pad disposed on the outer portion of the semiconductor chip. Thus, heights of different portions of the solder bump respectively on different positions of the semiconductor chip may be uniformly maintained, thereby more effectively coping with the misalignment.

The conductive material layer 400 may be disposed between the first and second semiconductor chips 100 and 200. The conductive material layer 400 may be on (e.g., partially cover) the bump structure 300.

The conductive material layer 400 may include a resin layer 401 and an inorganic filler 402 (e.g., spherical inorganic filler) contained in the resin layer 401. For example, the resin layer 401 may be an epoxy resin. However, the present disclosure is not limited thereto.

The inorganic filler 402 may include silica (SiO₂), alumina (Al₂O₃), silicon carbide (SiC), barium sulfate (BaSO₄), talc, clay, mica powder, aluminum hydroxide (Al(OH)₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃) and/or calcium zirconate (CaZrO₃). However, a material of the inorganic filler 402 is not limited thereto.

In some embodiments, a highly conductive filler may be used instead of a non-conductive film for the inorganic filler 402, such that heat dissipation of the semiconductor package may be further improved. Accordingly, in a process of bonding the semiconductor chips (e.g., first and second semiconductor chips 100 and 200) to each other, a yield of the semiconductor package may be further improved.

A plurality of alignment patterns 500 (e.g., 510, 520, 530, and 540 in FIG. 1) may be respectively adjacent to corners of the second semiconductor chip 200 in a plan view. The plurality of alignment patterns 500 may have different shapes. The plurality of alignment patterns 500 may be used to align positions of the first semiconductor chip 100 and the second semiconductor chip 200 with each other. In some embodiments, the plurality of alignment patterns 500 may be in the inner area IA.

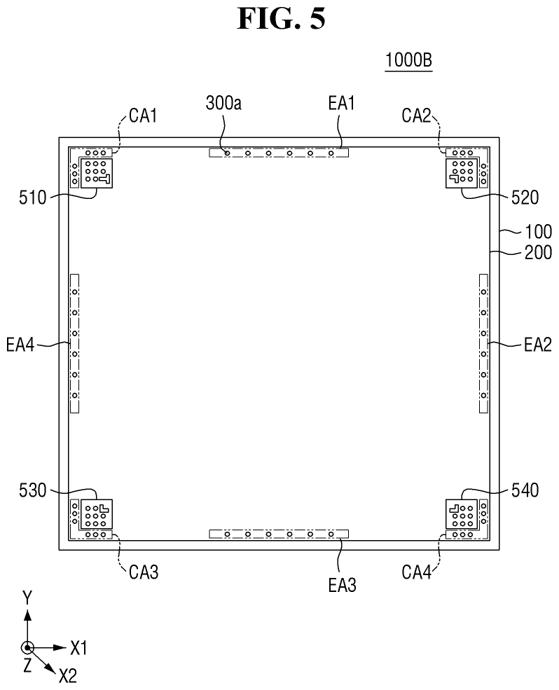

FIG. 5 is a plan view of an illustrative layout diagram of a semiconductor package according to some embodiments of the present disclosure. For convenience of description, descriptions duplicated with the descriptions as set forth above with reference to FIG. 1 to FIG. 4 maybe omitted.

In a semiconductor package 1000B of FIG. 5, the second semiconductor chip 200 may further include an edge area EA adjacent to the outer area CA. The edge area EA may include first to fourth edge areas EA1, EA2, EA3, and EA4 disposed adjacent to four corners of the second semiconductor chip 200, respectively. The first-first solder bump 300a may be further disposed in the edge area EA.

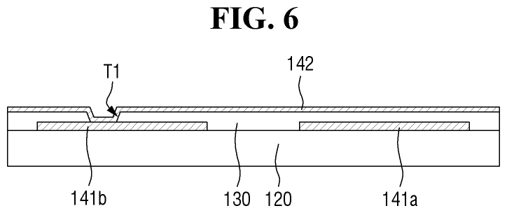

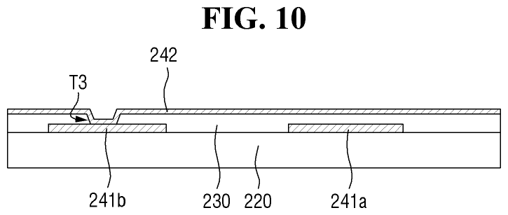

FIG. 6 to FIG. 9 are diagrams in cross-sectional views for illustrating a method for manufacturing a semiconductor package according to some embodiments of the present disclosure. FIG. 10 to FIG. 13 are diagrams in cross-sectional views for illustrating a method for manufacturing a semiconductor package according to some embodiments of the present disclosure. For convenience of description, descriptions duplicated with the descriptions as set forth above with reference to FIG. 1 to FIG. 5 may be omitted.

FIG. 6 to FIG. 9 are diagrams for illustrating a method for manufacturing a wiring pad of the first semiconductor chip 100. FIG. 10 to FIG. 13 are diagrams for illustrating a method for manufacturing a wiring pad and a solder bump of the second semiconductor chip 200.

Referring to FIG. 6, a first seed layer 142 may be formed on the first semiconductor device layer 120 and the first passivation layer 130 of the first semiconductor chip 100. A first trench T1 exposing a sidewall of the first passivation layer 130 and one face (e.g., a portion of a top face) of the first-first-second wiring pad 141b may be formed. The first seed layer 142 may be formed on the first trench T1.

The first seed layer 142 may be formed on the first-first-second wiring pad 141b so as to contact the exposed face of the first-first-second wiring pad 141b. The first seed layer 142 may be spaced apart from the first-first-first wiring pad 141a so as not to contact the first-first-first wiring pad 141a. For example, the first seed layer 142 may include titanium (Ti). However, the present disclosure is not limited thereto.

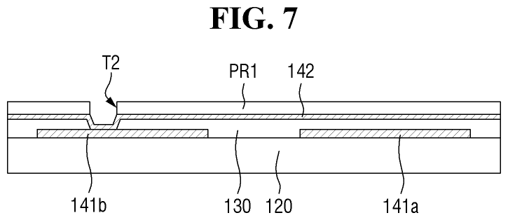

Referring to FIG. 7, a first photoresist PR1 may be formed on the first seed layer 142. At least a portion of the first photoresist PR1 may be removed to form a second trench T2. The first photoresist PR1 may expose a first partial area of the first seed layer 142 in contact with the first-first-second wiring pad 141b. The first partial area of the first seed layer 142 may be exposed from the first photoresist PR by the second trench T2. Thereafter, the first photoresist PR1 may expose a second partial area of the first seed layer 142 not in contact with the first-first-first wiring pad 141a. The second partial area of the first seed layer 142 may be overlapped with the first-first-first wiring pad 141a in the fourth direction Z.

For example, the first photoresist PR1 may include a photosensitive insulating material that may be used in an exposure process. However, the present disclosure is not limited thereto.

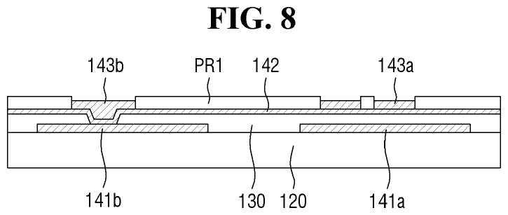

Referring to FIG. 8, each of the third-first-first 143a and the third-first-second 143b may be formed on each of partial portions (e.g., first and second partial areas) of the first seed layer 142 not covered with the first photoresist PR1 and spaced from each other. For example, each of the third-first-first 143a and the third-first-second 143b may be formed by plating nickel (Ni). However, the present disclosure is not limited thereto.

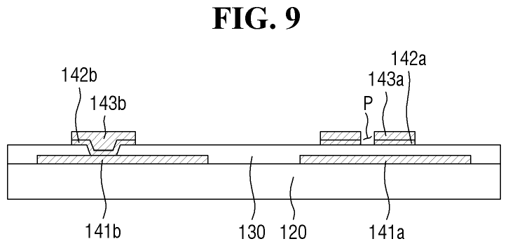

Referring to FIG. 9, the second-first-first wiring pad 142a and the second-first-second wiring pad 142b may be formed by removing the first photoresist PR1 and the first seed layer 142 below the first photoresist PR1.

The separation space P may be formed between the second-first-first wiring pads 142a and between the third-first-first wiring pads 143a. In this case, the first-first solder bump 300a formed later on the third-first-first wiring pads 143a may directly contact the first passivation layer 130.

For example, a plurality of third-first-first wiring pads 143a spaced apart from each other may be formed by forming the first photoresist PR1 in an area corresponding to an area where the third-first-first wiring pad 143a is not formed, and removing the first photoresist PR1 and the first seed layer 142 below the first photoresist PR1. However, the present disclosure is not limited thereto.

In another example, the separation space P may be formed only between the third-first-first wiring pads 143a, while the separation space P may not be formed between the second-first-first wiring pads 142a. In this case, the first-first solder bump 300a may not directly contact the first passivation layer 130 but may directly contact the second-first-first wiring pad 142a.

The removal of the first photoresist PR1 may be performed by an etching process of the photosensitive insulating material. The removal of the first seed layer 142 may be performed by an etching process of a metal material. However, the present disclosure is not limited thereto

Referring to FIG. 10, a second seed layer 242 may be formed on the second semiconductor device layer 220 and the second passivation layer 230 of the second semiconductor chip 200. A third trench T3 exposing a sidewall of the second passivation layer 230 and one face (e.g., a portion of a top face) of the first-second-second wiring pad 241b may be formed, and the second seed layer 242 may be formed on the third trench T3.

The second seed layer 242 may be formed on the first-second-second wiring pad 241b so as to contact the exposed face of the first-second-second wiring pad 241b. The second seed layer 242 may be spaced apart from the first-second-first wiring pad 241a so as not to contact the first-second-first wiring pad 241a. For example, the second seed layer 242 may include titanium (Ti). However, the present disclosure is not limited thereto.

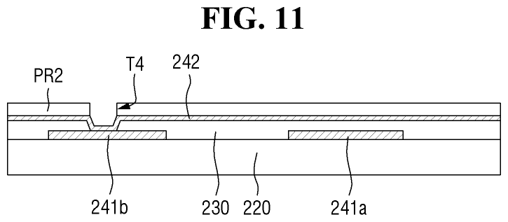

Referring to FIG. 11, a second photoresist PR2 may be formed on the second seed layer 242. At least a portion of the second photoresist PR2 may be removed to form a fourth trench T4. The second photoresist PR2 may expose a first partial area of the second seed layer 242 in contact with the first-second-second wiring pad 241b. The first partial area of the second seed layer 242 may be exposed from the second photoresist PR2 by the fourth trench T4. Thereafter, the second photoresist PR2 may expose a second partial area of the second seed layer 242 not in contact with the first-second-first wiring pad 241a. The second partial area of the second seed layer 242 may be overlapped with the first-second-first wiring pad 241a in the fourth direction Z.

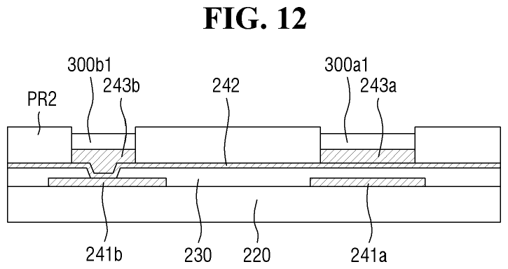

Referring to FIG. 12, each of the third-second-first 243a and the third-second-second wiring pad 243b may be respectively formed on partial portions (e.g., first and second partial areas) of the second seed layer 242 not covered with the second photoresist PR2 and spaced from each other. For example, each of the third-second-first 243a and the third-second-second wiring pad 243b may be formed by plating nickel (Ni). However, the present disclosure is not limited thereto.

Further, first and second solder layers 300a1 and 300b1 may be formed on the third-second-first 243a and the third-second-second wiring pad 243b, respectively. For example, the first and second solder layers 300a1 and 300b1 may be formed by plating tin (Sn). However, the present disclosure is not limited thereto.

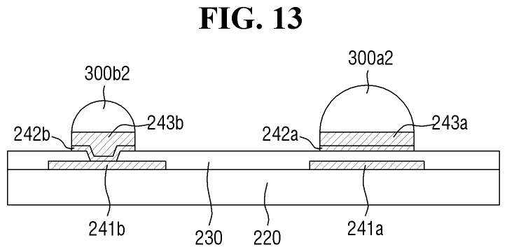

Referring to FIG. 13, the second-second-first wiring pad 242a and the second-second-second wiring pad 242b may be formed by removing the second photoresist PR2 and the second seed layer 242 below the second photoresist PR2.

Then, a first-first bump structure 300a2 on the second-second-first wiring pad 242a and the third-second-first wiring pad 243a and a first-second bump structure 300b2 on the second-second-second wiring pad 242b and the third-second-second wiring pad 243b may be formed. For example, this process may be performed by a reflow process.

Then, the first-first bump structure 300a2 and the first-second bump structure 300b2 of FIG. 13 may be on (e.g., bonded to) the third-first-first wiring pad 143a and the third-first-second wiring pad 143b of FIG. 9, respectively, such that the first-first solder bump 300a and the first-second solder bump 300b as shown in FIG. 3 may be formed, respectively. In this (e.g., bonding process), at least a portion of the first-first solder bumps 300a may be disposed between the plurality of third-first-first wiring pads 143a spaced apart from each other (e.g., separation space P).

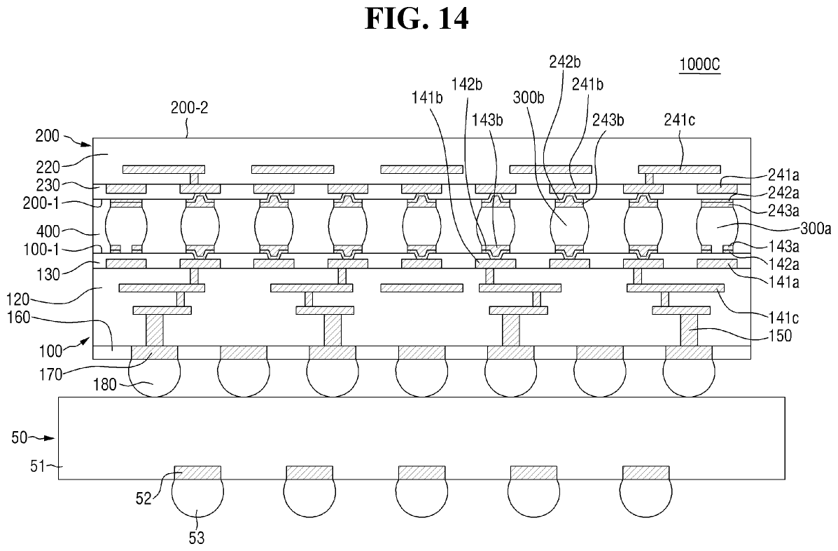

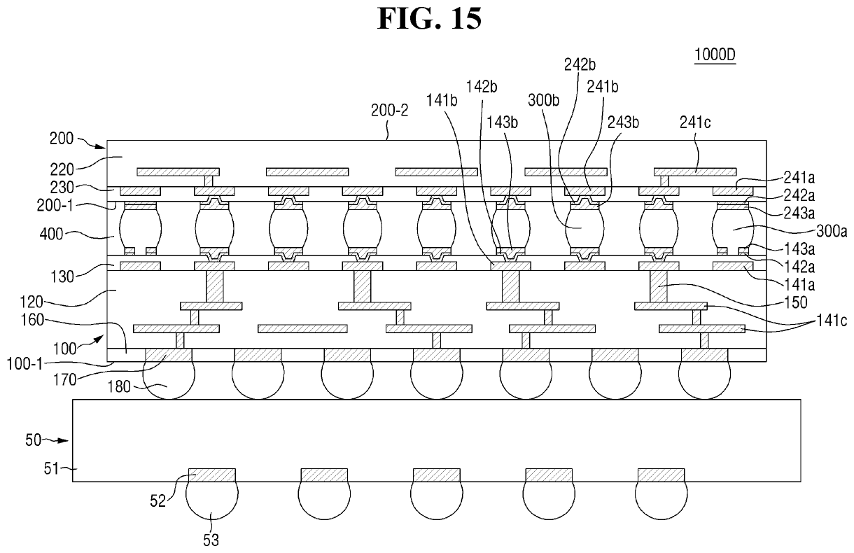

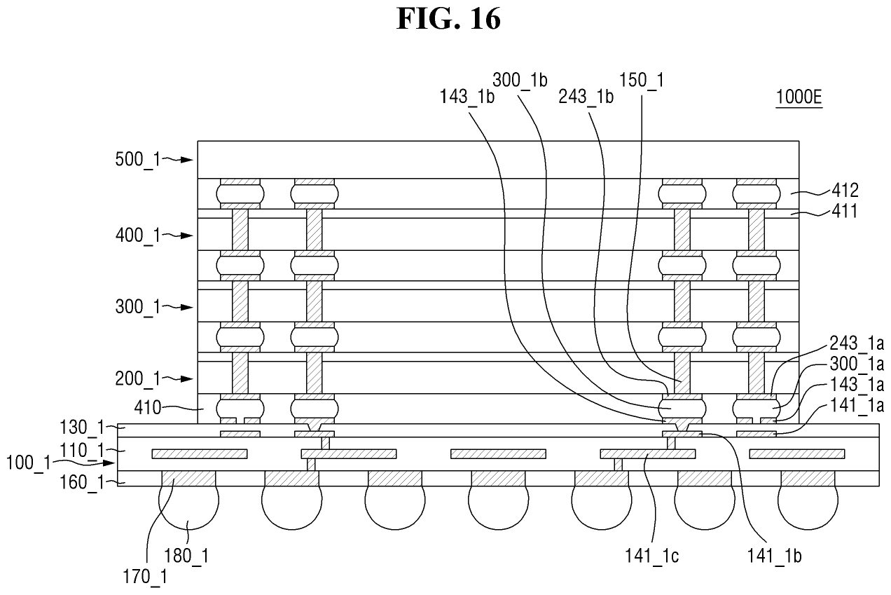

FIG. 14 is a diagram in a cross-sectional view for illustrating a semiconductor package according to some embodiments of the present disclosure. FIG. 15 is a diagram in a cross-sectional view for illustrating a semiconductor package according to some embodiments of the present disclosure. FIG. 16 is a diagram in a cross-sectional view for illustrating a semiconductor package according to some embodiments of the present disclosure. For the convenience of description, the descriptions duplicated with those as set forth above with reference to FIG. 1 to FIG. 13 may be omitted.

Referring to FIG. 14 and FIG. 15, each of semiconductor packages 1000C and 1000D may further include a base substrate 50. The base substrate 50 may extend in each of the first to third directions X1, X2, and Y intersecting each other.

The base substrate 50 may be, for example, a printed circuit board (PCB) or a ceramic substrate or an interposer. Alternatively, the base substrate 50 may be a semiconductor chip including a semiconductor device. However, the present disclosure is not limited thereto. The base substrate 50 may function as a support substrate of the semiconductor package. For example, the first semiconductor chip 100 as described above may be stacked on the base substrate 50.

The base substrate 50 may include a substrate body 51 and a bottom pad 52. The bottom pad 52 may be disposed at a bottom face of the substrate body 51. For example, the first semiconductor chip 100 may be disposed on a top face of the substrate body 51 that is opposite to the bottom face of the substrate body 51. An external connection terminal 53 may be disposed below the base substrate 50. The external connection terminal 53 may be disposed on the bottom pad 52. For example, the external connection terminal 53 may be a solder ball or a solder bump.

Wiring patterns electrically connected to the bottom pad 52 may be formed in the substrate body 51. The substrate body 51 is illustrated as a single layer. However, this is intended only for convenience of illustration. In some embodiments, the substrate body 51 may include multiple layers, and wiring patterns may be formed in each of the multiple layers.

Referring to FIGS. 14 and 15, the first semiconductor chip 100 may further include a through-via 150 extending through at least a portion of the first semiconductor chip 100 and electrically connecting the second semiconductor chip 200 and the base substrate 50 to each other.

The first semiconductor chip 100 may be stacked on the base substrate 50 in a vertical direction. The first semiconductor chip 100 may be electrically connected to the wiring patterns of the base substrate 50 via a connection structure 180. The connection structure 180 may be electrically connected to the base substrate 50 via a connection pad 170 disposed in a third passivation layer 160 below the first semiconductor chip 100.

The second semiconductor chip 200 may include an active face 200-1 and a non-active face 200-2 opposite to each other.

Referring to FIG. 14, an active face 100-1 of the first semiconductor chip 100 may face an active face 200-1 of the second semiconductor chip 200. In this case, the first semiconductor device layer 120 of the first semiconductor chip 100 and the second semiconductor device layer 220 of the second semiconductor chip 200 may face each other.

Referring to FIG. 15, the active face 200-1 of the second semiconductor chip 200 may be disposed to face a rear face of the first semiconductor chip 100, which is opposite to the active face 100-1 of the first semiconductor chip 100.

Referring to FIG. 16, a semiconductor package 1000E may include a plurality of semiconductor chips (e.g., a second semiconductor chip 300_1, a third semiconductor chip 400_1, and a fourth semiconductor chip 500_1) which may be disposed on a first semiconductor chip 200_1 and may be electrically connected to each other and the first semiconductor chip 200_1 via through-vias 150_1. For example, each of the first to fourth semiconductor chips 200_1, 300_1, 400_1, and 500_1 may be HBM (High Bandwidth Memory).

FIG. 16 illustrates an example in which the first semiconductor chip to the fourth semiconductor chips 200_1, 300_1, 400_1, and 500_1 are stacked on a substrate 100_1. However, the number of semiconductor chips stacked on the substrate 100_1 is not limited to four. For example, two, three, or five or more semiconductor chips may be stacked on the substrate 100_1.

In one example, the substrate 100_1 may be substantially the same as the base substrate 50 in FIG. 14. Although not specifically shown, the substrate 100_1 may include a plurality of wirings 141_1c and a plurality of vias electrically connected to the first semiconductor chip to the fourth semiconductor chips 200_1, 300_1, 400_1, and 500_1.

The substrate 100_1 may include a first wiring structure 110_1, a first passivation layer 130_1 on a top face of the first wiring structure 110_1, and a second passivation layer 160_1 on a bottom face of the first wiring structure 110_1.

A first-first wiring layer 141_1a and a first-second wiring layer 141_1b may be disposed in the first passivation layer 130_1. A first-first-first wiring pad 143_1a and a first-first-second wiring pad 143_1b may be disposed on the top face of the substrate 100_1.

A connection pad 170_1 connected to an external connection terminal 180_1 may be disposed in the second passivation layer 160_1.

A second-first-first wiring pad 243_1a and a second-first-second wiring pad 243_1b may be disposed under the first semiconductor chip 200_1. For example, the second-first-first wiring pad 243_1a and the second-first-second wiring pad 243_1b may be disposed on a bottom face of the first semiconductor chip 200_1.

A first-first bump structure 300_1a may be disposed between the second-first-first wiring pad 243_1a and the first-first-first wiring pad 143_1a in the fourth direction Z. A first-second bump structure 300_1b may be disposed between the second-first-second wiring pad 243_1b and the first-first-second wiring pad 143_1b in the fourth direction Z.

The first-second bump structure 300_1b may electrically connect the first semiconductor chip 200_1 and the substrate 100_1 to each other, while the first-first bump structure 300_1a may not electrically connect the first semiconductor chip 200_1 and the substrate 100_1 to each other.

A conductive material layer 410 may be interposed between the first-first bump structure 300_1a and the first-second bump structure 300_1b.

Each adhesive layer 411 may be interposed between adjacent ones of the first semiconductor chip to the fourth semiconductor chips 200_1, 300_1, 400_1, and 500_1 so as to attach adjacent ones of the first semiconductor chip to the fourth semiconductor chips 200_1, 300_1, 400_1, and 500_1 to each other.

Each mold layer 412 may be interposed between adjacent ones of the first semiconductor chip to the fourth semiconductor chips 200_1, 300_1, 400_1, and 500_1. The mold layer 412 may include an insulating polymeric material such as, for example, an EMC (epoxy molding compound). However, the present disclosure is not limited thereto.

Although the embodiments of the present disclosure have been described above with reference to the accompanying drawings, the present disclosure may not be limited to the embodiments and may be implemented in various different forms. Those of ordinary skill in the technical field to which the present disclosure belongs will be able to understand that the present disclosure may be implemented in other specific forms without changing the technical idea or essential features of the present disclosure. Therefore, it should be understood that the embodiments as described above are not restrictive but illustrative in all respects.

What is claimed is:

1. A semiconductor package comprising:
a first semiconductor chip, wherein the first semiconductor chip extends in each of first and second directions that intersect each other;
a second semiconductor chip stacked on the first semiconductor chip in a third direction perpendicular to each of the first and second directions, wherein the second semiconductor chip includes a first area and a second area that is adjacent to and extends around the first area;
a bump structure between the first and second semiconductor chips; and
a conductive material layer between the first and second semiconductor chips,
wherein the conductive material layer is on the bump structure,
wherein the bump structure includes a first bump structure overlapping the first area in the third direction, and a second bump structure overlapping the second area in the third direction,
wherein the first bump structure and the second bump structure are spaced apart from each other, and
wherein a thickness of the second bump structure in the third direction is larger than a thickness of the first bump structure in the third direction.

2. The semiconductor package of claim 1, wherein a maximum width of the second bump structure in the first direction is greater than a maximum width of the first bump structure in the first direction.

3. The semiconductor package of claim 1, wherein the first bump structure includes a first solder bump between a first-first wiring pad of the first semiconductor chip and a first-second wiring pad of the second semiconductor chip, and
wherein the second bump structure includes a second solder bump between a second-first wiring pad of the first semiconductor chip and a second-second wiring pad of the second semiconductor chip.

4. The semiconductor package of claim 3, wherein the second-first wiring pad of the first semiconductor chip includes a plurality of second-first wiring sub-pads that are spaced apart from each other,
wherein the second solder bump is between the plurality of second-first wiring sub- pads, and
wherein a thickness of the second solder bump in the third direction is larger than a thickness of the first solder bump in the third direction.

5. The semiconductor package of claim 4, wherein each of the plurality of second-first wiring sub-pads has an elliptical shape or a circular shape in a plan view of the semiconductor package.

6. The semiconductor package of claim 4, wherein each of the plurality of second-first wiring sub-pads has a rectangular shape in a plan view of the semiconductor package.

7. The semiconductor package of claim 1, wherein the first bump structure is electrically connected to the first and second semiconductor chips, and
wherein the second bump structure is electrically insulated from the first and second semiconductor chips.

8. The semiconductor package of claim 1, wherein the conductive material layer includes a resin layer and a filler in the resin layer.

9. The semiconductor package of claim 1, wherein the first semiconductor chip includes a first wiring structure and the second semiconductor chip includes a second wiring structure,
wherein the first and second wiring structures are electrically connected to the first bump structure, and
wherein the first and second wiring structures are electrically insulated from the second bump structure.

10. The semiconductor package of claim 1, further comprising a plurality of semiconductor chips on the first and second semiconductor chips and electrically connected to each other via a through-via.

11. A semiconductor package comprising:
a first semiconductor chip, wherein the first semiconductor chip extends in each of first and second directions that intersect each other;
a second semiconductor chip stacked on the first semiconductor chip in a third direction perpendicular to each of the first and second directions, wherein the second semiconductor chip includes a first area and a second area that is adjacent to and extends around the first area;
a bump structure between the first and second semiconductor chips; and
a conductive material layer between the first and second semiconductor chips, wherein the conductive material surrounds a portion of the bump structure,
wherein the bump structure includes:
a connection bump structure overlapping the first area in the third direction and electrically connected to the first and second semiconductor chips; and
a dummy bump structure overlapping the second area in the third direction and electrically insulated from the first and second semiconductor chips,
wherein the connection bump structure and the dummy bump structure are spaced apart from each other, and
wherein a thickness of the dummy bump structure in the third direction is larger than a thickness of the connection bump structure in the third direction.

12. The semiconductor package of claim 11, wherein a maximum width of the dummy bump structure in the first direction is larger than a maximum width of the connection bump structure in the first direction.

13. The semiconductor package of claim 11, wherein the dummy bump structure includes a first solder bump between a first-first wiring pad on the first semiconductor chip and a first-second wiring pad on the second semiconductor chip,
wherein the connection bump structure includes a second solder bump between a second-first wiring pad on the first semiconductor chip and a second-second wiring pad on the second semiconductor chip, and
wherein the first-first wiring pad on the first semiconductor chip includes a plurality of first-first wiring sub-pads spaced apart from each other.

14. The semiconductor package of claim 13, wherein the first solder bump is between the first-first wiring sub-pads that are spaced apart from each other in the first direction.

15. The semiconductor package of claim 13, wherein a thickness of the first solder bump in the third direction is larger than a thickness of the second solder bump in the third direction.

16. The semiconductor package of claim 11, wherein the conductive material layer includes a resin layer and a filler in the resin layer.

17. The semiconductor package of claim 11, further comprising a plurality of alignment patterns in the first area in a plan view of the semiconductor package.

18. A semiconductor package comprising:
a substrate, wherein the substrate extends in each of first and second directions that intersect each other;
a first semiconductor chip stacked on the substrate in a third direction perpendicular to each of the first and second directions;
a second semiconductor chip stacked on the first semiconductor chip in the third direction, wherein the second semiconductor chip includes a first area and a second area that is adjacent to and extends around the first area;
a bump structure that is configured to bond the first semiconductor chip and the second semiconductor chip to each other between the first semiconductor chip and the second semiconductor chip; and
a conductive material layer between the first and second semiconductor chips, wherein the conductive material surrounds a portion of the bump structure,
wherein the first semiconductor chip includes a through-via extending through at least a portion of the first semiconductor chip, wherein the through-via electrically connects the second semiconductor chip and the substrate to each other,
wherein the bump structure includes a first bump structure overlapping the first area in the third direction, and a second bump structure overlapping the second area in the third direction, and
wherein a thickness of the first bump structure in the third direction is different from a thickness of the second bump structure in the third direction.

19. The semiconductor package of claim 18, wherein the thickness of the second bump structure in the third direction is larger than the thickness of the first bump structure in the third direction, and
wherein a width of the second bump structure in the first direction is greater than a width of the first bump structure in the first direction.

20. The semiconductor package of claim 18, wherein the first bump structure is electrically connected to the first and second semiconductor chips, and
wherein the second bump structure is electrically insulated from the first and second semiconductor chips.
